(19) United States
(12) Patent Application Publication
(10) Pub. No.: US 2009/0166717 A1
(43) Pub. Date: Jul. 2, 2009

(54) NONVOLATILE MEMORY DEVICE AND METHOD FOR MANUFACTURING THE SAME

(76) Inventor: Jin-Hyo Jung, Suwon-si (KR)

Correspondence Address: SHERR & VAUGHN, PLLC, 620 HERNDON PARKWAY, SUITE 200, HERNDON, VA, 20170, US

(21) Appl. No.: 12/344,557

(22) Filed: Dec. 28, 2008

(30) Foreign Application Priority Data
Dec. 28, 2007 (KR) 10-2007-0139622

(51) Int. Cl. H01L 29/792; H01L 21/8239

(52) U.S. Cl. 257/324; 438/287; 257/E29.309; 257/E21.423

(57) ABSTRACT

Embodiments relate to a nonvolatile memory device and a method for manufacturing the same. According to embodiments, a nonvolatile memory device may include a tunnel ONO film having an oxide film, a nitride film, and an oxide film stacked on and/or over a semiconductor substrate. It may also include a trap nitride film formed on and/or over the tunnel ONO film, a blocking oxide film formed on and/or over the trap nitride film and having a high-dielectric film with a higher dielectric constant than a dielectric constant of a SiO₂ film. According to embodiments, a gate may be formed on and/or over the blocking oxide film. An electron back F/N tunneling at the time of an erase operation may be minimized. This may improve an erase speed and erase Vt saturation phenomenon.

The present application claims priority under 35 U.S.C. 119 to Korean Patent Application No. 10-2007-0139622 (filed on Dec. 28, 2007), which is hereby incorporated by reference in its entirety.

### BACKGROUND

A nonvolatile memory device may be a floating gate-based nonvolatile memory device. When a floating gate-based nonvolatile memory device is scaled to a size that may not exceed 60 nm, a cell-to-cell Vₜ distribution may become relatively large due to a cell-to-cell interference effect. This may cause an error due to a misread out that may be generated when reading out data. There may therefore be a need for a nonvolatile memory device with which the floating gate-based nonvolatile memory device may be replaced.

One device that has been identified may be a Silicon-Oxide-Nitride-Oxide-Silicon (SONOS) device. A SONOS device may operate as a nonvolatile memory device by trapping or de-trapping an electron or a hole into a trap site present within a nitride film. Such a SONOS device may not have the cell-to-cell interference effect. Hence, although a SONOS device may be scaled to a size not exceeding 60 nm, it may not cause a problem where a cell-to-cell threshold voltage (Vt) distribution becomes relatively large due to the cell-to-cell interference effect. Therefore, a next generation nonvolatile memory, which may be a NAND flash memory device, may become important. In a SONOS device, a program operation or an erase operation may be performed by tunneling an electron or a hole. This may be disadvantageous in that characteristics of a SONOS device may react sensitively according to a thickness of a tunnel oxide film. For example, if a thickness of a tunnel oxide film increases, retention characteristics may be improved, but an erase speed may be degraded. To the contrary, if a thickness of a tunnel oxide film decreases, an erase speed may be improved, but retention characteristics may be degraded. As described above, in a SONOS device-based nonvolatile memory device, an erase speed and retention characteristics may be in a trade-off relation with each other. Accordingly, a SONOS device structure which may simultaneously improve an erase speed and retention characteristics may be important.

FIG. 1 is a schematic cross-sectional view illustrating a SONONOS (also sometimes referred to as BE-SONOS) structure. Referring to FIG. 1, in a SONONOS structure, tunnel oxide film 102, buffer nitride film 103, buffer oxide film 104, trap nitride film 105, blocking oxide film 106, and gate 110 may be stacked sequentially on and/or over semiconductor substrate 10. Blocking oxide film 106 may be formed of a SiO₂ film. Gate 110 may be formed of poly silicon. Tunnel oxide film 102, buffer nitride film 103, and buffer oxide film 104 may form ONO barrier film 100. The device may also include source 12 and drain 14.

FIG. 2 is an energy band diagram in a SONONOS structure of FIG. 1. Referring to FIGS. 1 and 2, a SONONOS or BE-SONOS structure may use an ONO film, instead of a tunnel oxide film that may be used in other SONOS devices. In a SONONOS structure or a BE-SONOS structure, in program/erase operations, an electron or a hole may be tunneled using an oxide film on and/or over a silicon substrate and may make program/erase speed fast. In a retention mode, retention characteristics may be improved by reducing a possibility to generate back-tunneling of an electron or a hole trapped by functioning as a tunnel oxide film through an entire thickness of ONO film 100, which may be used instead of the tunneling oxide film.

FIG. 3 is a graph illustrating an erase threshold voltage (Vt) saturation of a SONONOS structure. In such a SONONOS structure, an erase speed and retention characteristics may be simultaneously improved by replacing a tunneling oxide film with an ONO film. As shown in FIG. 3, however, an erase Vt saturation phenomenon may be generated in a same manner as other SONOS devices. For example, an erase Vt saturation phenomenon may occur by a back Fowler-Nordheim (F/N) tunneling electron that may be injected into trap nitride film 105 by F/N tunneling blocking oxide film 106 from gate 110 at a time of an erase operation. There may therefore be a limitation in increasing an erase speed in a memory device having the SONONOS or BE-SONOS structure. Furthermore, Vt in an erase state may not be able to fall below a predetermined value of erase Vt, which may limit implementing a multi-level bit.

### SUMMARY

Embodiments relate to a nonvolatile memory device and a method for manufacturing a nonvolatile memory device. Embodiments relate to a quantum trap nonvolatile memory device that may include a Silicon-Oxide-Nitride-Oxide-Nitride-Oxide-Silicon (SONONOS) or a Bandgap Engineered SONOS (BE-SONOS) structure, and a method for manufacturing the device.

According to embodiments, a nonvolatile memory device may improve erase speed by improving an erase Vt saturation phenomenon generated from a SONONOS device or a BE-SONOS device and may implement a multi-level bit by widening a Vt window, and a method for manufacturing the same.

According to embodiments, a nonvolatile memory device may include at least one of the following. A tunnel ONO film having a structure that an oxide film, a nitride film, and an oxide film may be stacked on and/or over a semiconductor substrate. A trap nitride film formed on and/or over the tunnel ONO film. A blocking oxide film formed on and/or over the trap nitride film and that may be formed of a high-dielectric film having a higher dielectric constant than a dielectric constant of a SiO₂ film. A gate formed on and/or over the blocking oxide film.

According to embodiments, a nonvolatile memory device may include at least one of the following. A tunnel ONO film having a structure that an oxide film, a nitride film, and an oxide film may be stacked on and/or over a semiconductor substrate. A trap nitride film formed on and/or over the tunnel ONO film. A blocking oxide film formed on and/or over the trap nitride film. A metal gate formed on and/or over the blocking oxide film.

According to embodiments, a method for manufacturing a nonvolatile memory device may include at least one of the following. Forming a tunnel ONO film including an oxide film, a nitride film, and an oxide on and/or over a semiconductor substrate. Forming a trap nitride film on and/or over the tunnel ONO film. Forming a blocking oxide film of a high-dielectric film having a higher dielectric constant than a dielectric constant of a SiO₂ film on and/or over the trap nitride film. Forming a gate on and/or over the blocking oxide film.

According to embodiments, a method for manufacturing a nonvolatile memory device may include at least one of the following. Forming a tunnel ONO film having an oxide film, a nitride film, and an oxide film on and/or over a semiconductor substrate. Forming a trap nitride film on and/or over the tunnel ONO film. Forming a blocking oxide film on and/or over the trap nitride film. Forming a metal gate on and/or over the blocking oxide film.

### DRAWINGS

FIG. 1 is a schematic cross-sectional view illustrating a SONONOS or BE-SONOS structure.

FIG. 2 is an energy band diagram of the SONONOS structure of FIG. 1.

FIG. 3 is a graph illustrating an erase threshold voltage (Vt) saturation of a SONONOS structure.

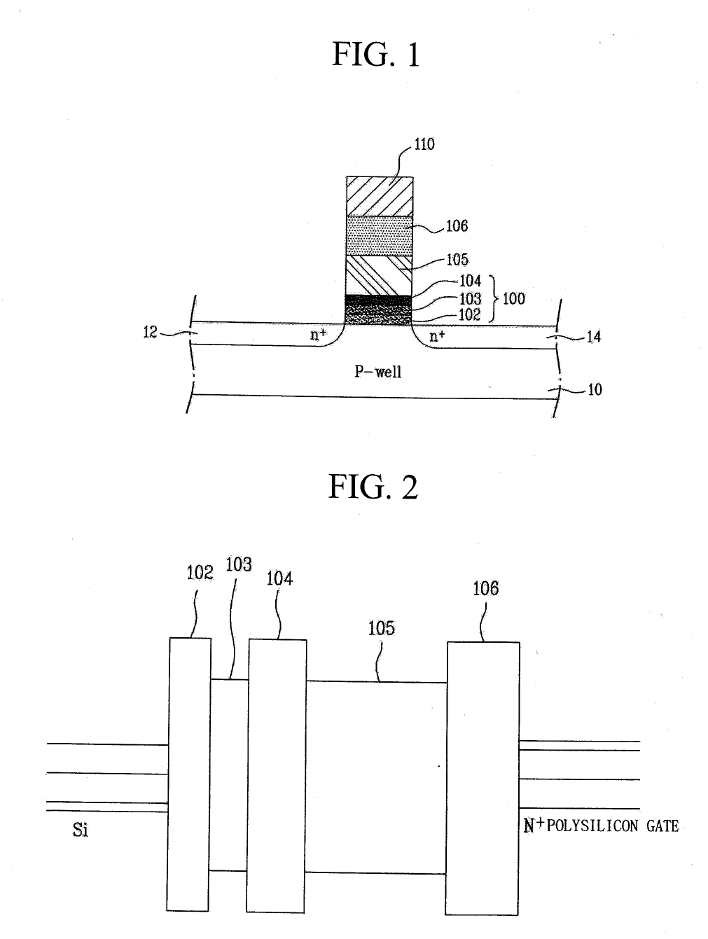

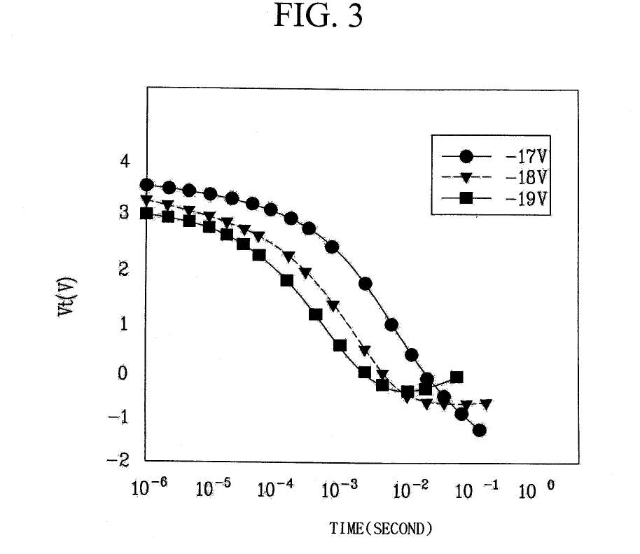

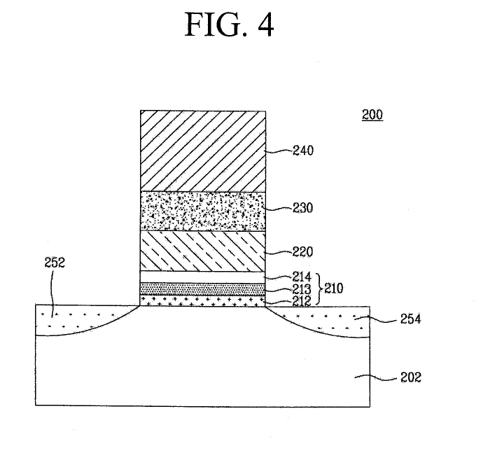

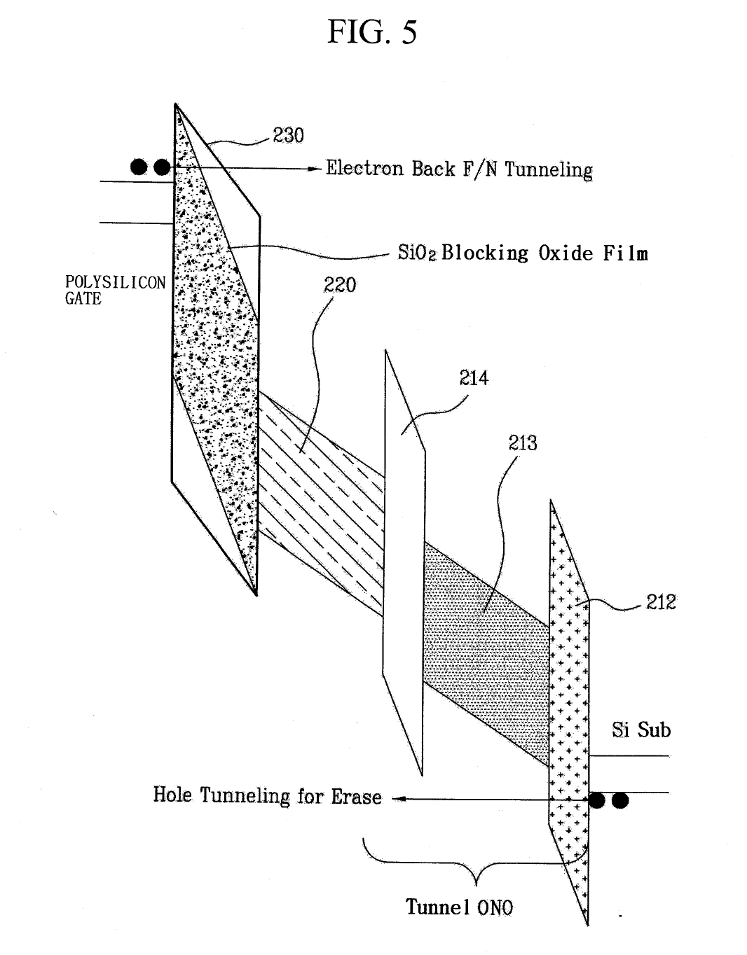

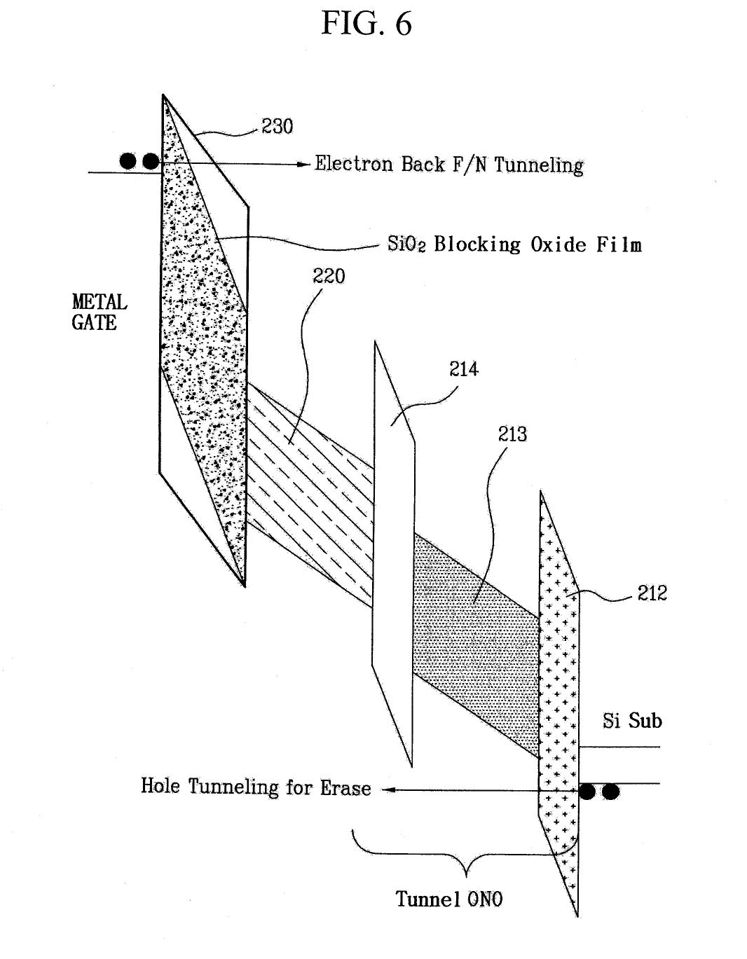

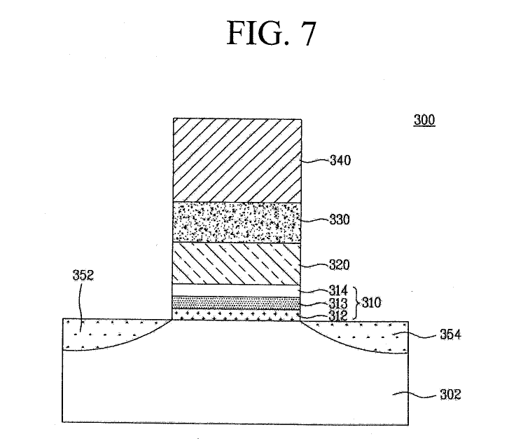

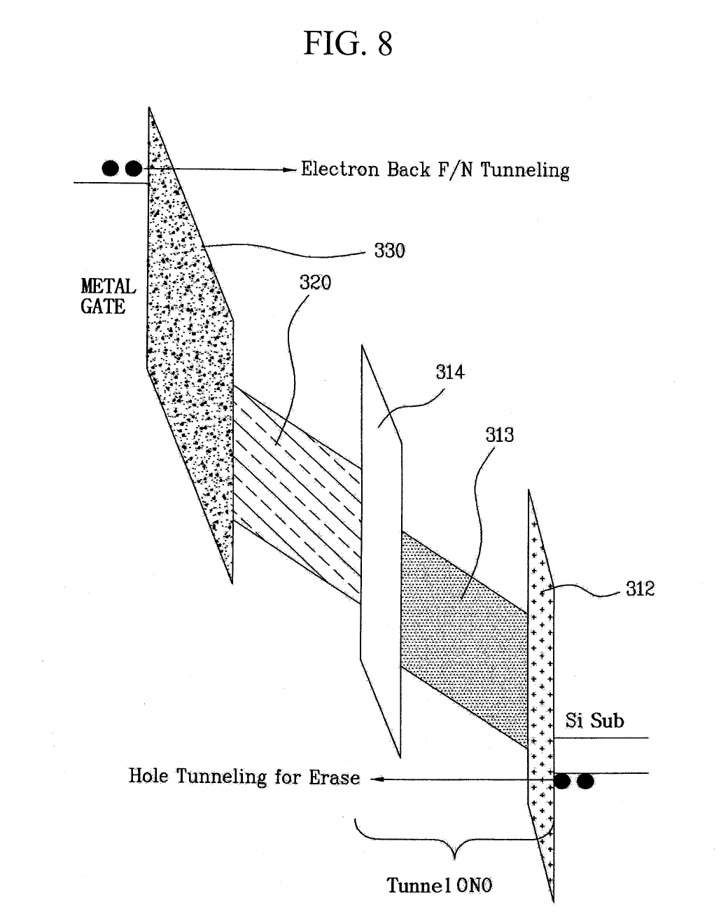

Example FIG. 4 is a cross-sectional view illustrating a nonvolatile memory device according to embodiments.

Example FIG. 5 is a graph illustrating a coupling relation of an energy band according to embodiments of a nonvolatile memory device of example FIG. 4.

Example FIG. 6 is a graph illustrating a coupling relation of an energy band according to embodiments of a nonvolatile memory device of example FIG. 4.

Example FIG. 7 is a cross-sectional view illustrating a nonvolatile memory device according to embodiments.

Example FIG. 8 is a graph showing a coupling relation of an energy band according to embodiments of a nonvolatile memory device of example FIG. 7.

### DESCRIPTION

Example FIG. 4 is a cross-sectional view illustrating a nonvolatile memory device according to embodiments. Referring to example FIG. 4, nonvolatile memory device 200 may include tunnel ONO film 210 and trap nitride film 220 formed on and/or over tunnel ONO film 210. It may further include blocking oxide film 230 formed on and/or over trap nitride film 220, and gate 240 formed on and/or over blocking oxide film 230. According to embodiments, these elements may be sequentially stacked on and/or over semiconductor substrate 202. According to embodiments, tunnel ONO film 210 may include oxide film 212, nitride film 213, and oxide film 214, which may be stacked. The device may also include source 252 and drain 254. According to embodiments, blocking oxide film 230 may be formed of a high-dielectric film, which may have a higher dielectric constant than a dielectric constant of a SiO₂ film. According to embodiments, blocking oxide film 230 may be an Al₂O₃ film. Gate 240 may be formed of poly silicon or metal. According to embodiments, if gate 240 is formed of metal, gate 240 may be formed of at least one of TiN and TaN. Trap nitride film 220 may be formed of at least one of a silicon nitride film and a silicon oxy-nitride film.

Example FIG. 5 is a graph showing a coupling relation of an energy band according to embodiments of nonvolatile memory device 200 of example FIG. 4. In nonvolatile memory device 200 of FIG. 5, blocking oxide film 230 may be formed of an Al₂O₃ film, and gate 240 may be formed of poly silicon. An energy band in which blocking oxide film 230 may be formed of a SiO₂ film, is also illustrated in example FIG. 5. Referring to example FIG. 5, since blocking oxide film 230 may be formed of an Al₂O₃ film, a tunneling length of an electron undergoing back F/N tunneling in gate 240 formed of poly silicon at the time of an erase operation may become longer by about 2-2.5 times, as compared to a example in which a SiO₂ blocking oxide film is used. This may be because a dielectric constant of an Al₂O₃ film may be larger than a dielectric constant of a SiO₂ film by about 2-2.5 times. Since the tunneling current may be reduced exponentially according to a tunneling length, blocking oxide film 230 may be formed of a high-dielectric film such as an Al₂O₃ film. This may suppress an electron back F/N tunneling in gate 240 during an erase operation. This may allow an erase speed and erase Vt saturation phenomenon to be maximized.

Example FIG. 6 is a graph illustrating a coupling relation of an energy band according to embodiments of nonvolatile memory device 200 of example FIG. 4. In nonvolatile memory device 200 of example FIG. 6, blocking oxide film 230 may be formed of an Al₂O₃ film, and gate 240 may be formed of metal. An energy band in which blocking oxide film 230 may be formed of a SiO₂ film, is also illustrated in example FIG. 6. Referring to example FIG. 6, blocking oxide film 230 may have a SONONOS (BE-SONOS) structure and may be formed of a high-dielectric film such as Al₂O₃ film, instead of SiO2 film. Gate 240 may be formed of metal. Accordingly, an electron back F/N tunneling during an erase operation may be suppressed, which may make it possible to maximize an erase speed and erase Vt saturation phenomenon.

Example FIG. 7 is a cross-sectional view illustrating nonvolatile memory device 300 according embodiments. Referring to example FIG. 7, nonvolatile memory device 300 may include tunnel ONO film 310, trap nitride film 320 formed on and/or over tunnel ONO film 310, and blocking oxide film 330 formed on and/or over trap nitride film 320. It may also include gate 340 formed on and/or over blocking oxide film 330. According to embodiments, these elements may be sequentially stacked on and/or over semiconductor substrate 302. According to embodiments, tunnel ONO film 310 may include oxide film 312, nitride film 313, and oxide film 314, which may be stacked. The device may also include source 352 and drain 354. According to embodiments, blocking oxide film 330 may be formed of an SiO₂ film. Gate 340 may be formed of metal. According to embodiments, gate 340 may be formed of at least one of TiN and TaN. According to embodiments, trap nitride film 320 may be formed of at least one of a silicon nitride film and a silicon oxy-nitride film.

Example FIG. 8 is a graph illustrating a coupling relation of an energy band according to embodiments of nonvolatile memory device 300 of FIG. 7. In nonvolatile memory device 300 of FIG. 8, blocking oxide film 330 may be formed of a SiO₂ film, and gate 340 may be formed of metal. Referring to example FIG. 8, if gate 340 is formed of metal, a conduction band of metal gate 340 may exist in a mid-gap region of Si. Accordingly, a tunneling length of an electron undergoing back F/N tunneling in gate 340 formed of metal during an erase operation may become longer as compared to an example in which the gate may be formed of poly silicon. This may be because offset of gate 340, formed of metal, conduction band for blocking oxide film 330 conduction band may be larger than that of gate 340, formed of poly silicon, conduction band for blocking oxide film conduction band 330. According to embodiments, since a tunneling current may be reduced exponentially according to a tunneling length, a metal gate may be used so that the electron back F/N tunneling in a poly silicon gate during an erase operation may be suppressed. This may make it possible to improve an erase speed and erase Vt saturation phenomenon.

A method for manufacturing a nonvolatile memory device according to embodiments will be described with reference to example FIG. 4. Tunnel ONO film 210 may be formed on and/or over semiconductor substrate 202. According to embodiments, tunnel ONO film 210 may include oxide film 212, nitride film 213, and oxide film 214, which may be stacked.

Trap nitride film 220 may be formed on and/or over tunnel ONO film 210. Trap nitride film 220 may be formed of one of a silicon nitride film and a silicon oxy-nitride film. Blocking oxide film 230 may be formed of a high-dielectric film, which may have a higher dielectric constant than a dielectric constant of a SiO₂ film, and may be formed on and/or over trap nitride film 220. According to embodiments, blocking oxide film 230 may be formed of an Al₂O₃ film. Gate 240 may be formed on and/or over blocking oxide film 230. Gate 240 may be formed of at least one of poly silicon and metal. If gate 240 is formed of metal, gate 240 may be formed of at least one of TiN and TaN. Referring to example FIG. 4, a nonvolatile memory device may be formed by sequentially stacking oxide film 212, nitride film 213, oxide film 214, trap nitride film 220, blocking oxide film 230, and material layers for gate 240. The layers may then be patterned.

A method for manufacturing a nonvolatile memory device according embodiments will next be described with reference to example FIG. 7. Referring to example FIG. 7, tunnel ONO film 310 may be formed on and/or over semiconductor substrate 302. According to embodiments, tunnel ONO film 310 may include oxide film 312, nitride film 313, and oxide film 314, which may be stacked. Trap nitride film 320 may be formed on and/or over tunnel ONO film 310. According to embodiments, blocking oxide film 330 may be formed on and/or over trap nitride film 320. For example, blocking oxide film 330 may be formed of a SiO₂ film. A metal gate 340 may be formed on and/or over blocking oxide film 330. According to embodiments, gate 340 may be formed of at least one of TiN and TaN.

Referring to example FIG. 7, a nonvolatile memory device may be formed by sequentially stacking oxide film 312, nitride film 313, oxide film 314, trap nitride film 320, blocking oxide film 330, and material layers for gate 340 on and/or over the semiconductor substrate 302. According to embodiments, these layers may then be patterned.

A nonvolatile memory device and a method for manufacturing the same according to embodiments may use a SONONOS or a BE-SONOS structure, and may use a high blocking film formed of a high-dielectric film such as Al₂O₃ film, instead of SiO₂ film, or a metal gate. Since a high-dielectric film such as Al₂O₃ film may be used as the blocking oxide film, an electron back F/N tunneling at the time of an erase operation may be minimized. This may make it possible to improve an erase speed and erase Vt saturation phenomenon.

A conduction band of a metal gate may exist in a mid-gap region of Si, so a tunneling length of an electron undergoing back F/N tunneling in the metal gate at the time of an erase operation may become longer as compared to an example in which a gate is formed of poly silicon. Therefore, an electron back F/N tunneling during an erase operation may be suppressed by using a metal gate. This may make it possible to improve an erase speed and erase Vt saturation phenomenon. Embodiments may thus provide a nonvolatile memory device, which may implement a multi-level bit by widening a Vt window.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a tunnel Oxide-Nitride-Oxide (ONO) film including an oxide film, a nitride film, and an oxide film stacked over a semiconductor substrate;
a trap nitride film formed over the tunnel ONO film;
a blocking oxide film formed over the trap nitride film and formed of a high-dielectric film having a higher dielectric constant rather than a dielectric constant of a SiO₂ film; and
a gate formed over the blocking oxide film.

2. The device of claim 1, wherein the blocking oxide film comprises an Al₂O₃ film.

3. The device of claim 1, wherein the gate comprises poly silicon.

4. The device of claim 1, wherein the gate comprises metal.

5. The device of claim 4, wherein the gate comprises one of TiN and TaN.

6. The device of claim 1, wherein the trap nitride film comprises one of a silicon nitride film and a silicon oxy-nitride film.

7. The device of claim 1, further comprising a source region and a drain region formed in the semiconductor substrate.

8. A device comprising:
a tunnel Oxide-Nitride-Oxide (ONO) film including an oxide film, a nitride film, and an oxide film stacked over a semiconductor substrate;
a trap nitride film formed over the tunnel ONO film;
a blocking oxide film formed over the trap nitride film; and
a metal gate formed over the blocking oxide film.

9. The device of claim 8, wherein the blocking oxide film comprises a SiO₂ film.

10. The device of claim 8, wherein the gate comprises one of TiN and TaN.

11. The device of claim 8, further comprising a source region and a drain region formed in the semiconductor substrate.

12. The device of claim 8, wherein the trap nitride film comprises one of a silicon nitride film and a silicon oxy-nitride film.

13. A method comprising:
forming a tunnel Oxide-Nitride-Oxide (ONO) by stacking an oxide film, a nitride film, and an oxide film over a semiconductor substrate;
forming a trap nitride film over the tunnel ONO film;
forming a blocking oxide film over the trap nitride film, the blocking oxide film being a high-dielectric film having a higher dielectric constant than a dielectric constant of a SiO₂ film; and
forming a gate over the blocking oxide film.

14. The method of claim 13, wherein the blocking oxide film comprises an Al₂O₃ film.

15. The method of claim 13, wherein the gate comprises poly silicon.

16. The method of claim 13, wherein the gate comprises metal.

17. The method of claim 16, wherein the gate comprises one of TiN and TaN.

18. The method of claim 13, wherein the trap nitride film comprises one of a silicon nitride film and a silicon oxy-nitride film.

19. The method of claim 11, further comprising forming a source region and a drain region in the semiconductor substrate.

20. The method of claim 13, wherein the blocking oxide film comprises a SiO₂ film.
